(19) United States
(12) Patent Application Publication
(10) Pub. No.: US 2026/0047449 A1
(43) Pub. Date: Feb. 12, 2026

(54) LEAD-FRAME PACKAGE UTILIZING INTEGRATED INSULATING LAYER FOR INTEGRATED CIRCUIT INSULATION

(71) Applicant: STMicroelectronics International N.V., Geneva (CH)

(72) Inventors: Mark Andrew Shaw, Milano (IT); Alex Gritti, Vimercate (IT)

(21) Appl. No.: 18/796,554

(22) Filed: Aug. 7, 2024

(51) Int. Cl. H01L 23/495; H01L 23/498

(52) U.S. Cl. CPC H10W 70/465; H10W 70/415; H10W 70/424; H10W 90/701

(57) ABSTRACT

An example lead-frame package, a method of manufacturing the lead-frame package, and an electrical system comprising the lead-frame package utilizing an integrated insulating layer to electrically insulate an integrated circuit within the lead-frame package from one or more electrical components are provided. The example lead-frame package includes an integrated circuit substrate and an integrated circuit. An integrated insulating layer forms a first surface of the integrated circuit substrate. A plurality of conductive leads provides a conductive path between a second surface of the integrated circuit substrate and the first surface, with a conductive trace formed within the integrated circuit substrate. The integrated insulating layer defines conductive wirebond pads providing an electrical connection to the plurality of conductive leads. In addition, the integrated circuit is electrically isolated from the conductive trace by the integrated insulating layer, wherein the integrated circuit is positioned to determine an electromagnetic property of the conductive trace.

### TECHNOLOGICAL FIELD

Embodiments of the present disclosure relate generally to lead-frame packages, and more particularly, to integrating an insulation layer within the integrated circuit (IC) substrate of a lead-frame package.

### BACKGROUND

Many electronic systems utilize printed circuit boards (PCBs) to support and connect the various electrical components of the electrical system. A PCB may commonly receive surface-mounted and/or socketed electrical components, such as lead-frame packages including various integrated circuits (ICs) configured to perform various operations. Some lead-frame packages require electrical insulation of the IC from one or more electrical components within the lead-frame package.

Applicant has identified many technical challenges and difficulties associated with electrically insulating an IC from one or more electrical components within a lead-frame package. Through applied effort, ingenuity, and innovation, Applicant has solved problems related to the electrical insulation of the IC by developing solutions embodied in the present disclosure, which are described in detail below.

### BRIEF SUMMARY

Various embodiments are directed to an example lead-frame package, a method of manufacturing a lead-frame package, and an electrical system comprising a lead-frame package utilizing an integrated insulating layer to electrically insulate an integrated circuit within the lead-frame package from one or more electrical components. An example lead-frame package may comprise an integrated circuit substrate having a plurality of conductive leads, a conductive trace, and an integrated insulating layer; and an integrated circuit. The integrated circuit substrate comprising at least a first surface and a second surface opposite the first surface. The plurality of conductive leads providing a conductive path between the second surface and the first surface, with the conductive trace formed within the integrated circuit substrate. The integrated insulating layer forming the first surface of the integrated circuit substrate, the integrated insulating layer defining a plurality of conductive wirebond pads associated with the plurality of conductive leads and providing an electrical connection to the plurality of conductive leads. In addition, the integrated circuit electrically isolated from the conductive trace by the integrated insulating layer, wherein the integrated circuit is positioned to determine an electromagnetic property of the conductive trace, and wherein the integrated circuit is electrically connected to the plurality of conductive leads.

In some embodiments, the integrated circuit is configured to determine a current flow through the conductive trace based at least in part on the electromagnetic property.

In some embodiments, a first portion of the conductive trace is within a projection of an outer perimeter of the integrated circuit has a smaller cross-sectional area than a second portion of the conductive trace outside of the projection of the outer perimeter of the integrated circuit.

In some embodiments, the first portion of the conductive trace is curved.

In some embodiments, the integrated insulating layer comprises a dielectric buildup film.

In some embodiments, the dielectric buildup film is between 40 and 60 micrometers thick.

In some embodiments, the dielectric buildup film is integrated with the integrated circuit substrate.

In some embodiments, the conductive wirebond pads providing an electrical connection to the plurality of conductive leads are each smaller than 10000 square micrometers.

In some embodiments, the conductive leads are formed through a copper connection in molding (C2iM) process.

In some embodiments, the integrated circuit is in a flip-chip configuration such that electrical contact points on the integrated circuit are between the first surface of the integrated circuit substrate and the integrated circuit.

In some embodiments, an electrical connection is made between the electrical contact points on the integrated circuit and the plurality of conductive wirebond pads on the integrated circuit substrate.

In some embodiments, the lead-frame package further comprises one or more adhesive connectors adhering the integrated circuit to the first surface of the integrated circuit substrate.

In some embodiments, the integrated circuit is embedded in the lead-frame package between package molding and the integrated circuit substrate.

In some embodiments, panel level package technology is utilized to embed the integrated circuit between the package molding and the integrated circuit substrate.

A method of manufacturing a lead-frame package is further provided. In some embodiments, the method comprises: forming an integrated circuit substrate comprising at least a first surface and a second surface opposite the first surface, the integrated circuit substrate defining a plurality of conductive leads providing a conductive path between the second surface and the first surface. The method further comprises forming a conductive trace within the integrated circuit substrate. In addition, the method comprises disposing an integrated insulating layer on the integrated circuit substrate forming the first surface of the integrated circuit substrate, the integrated insulating layer defining a plurality of conductive wirebond pads associated with the plurality of conductive leads and providing an electrical connection to the plurality of conductive leads. Further, the method comprises positioning an integrated circuit on the first surface of the integrated circuit substrate, wherein the integrated circuit is electrically isolated from the conductive trace by the integrated insulating layer, wherein the integrated circuit is positioned to determine an electromagnetic property of the conductive trace, and wherein the integrated circuit is electrically connected to the plurality of conductive leads.

In some embodiments, the integrated insulating layer comprises a dielectric buildup film.

In some embodiments, the integrated circuit is configured to determine a current flow through the conductive trace based at least in part on the electromagnetic property.

In some embodiments, the integrated circuit substrate comprising the plurality of conductive leads and the conductive trace is formed through a copper connection in molding (C2iM) process.

In some embodiments, the integrated circuit is positioned such that a first portion of the conductive trace within a projection of an outer perimeter of the integrated circuit has a smaller cross-sectional area than a second portion of the conductive trace outside of the projection of the outer perimeter of the integrated circuit.

An electrical system is further provided. In some embodiments, the electrical system comprises a lead-frame package and a printed circuit board (PCB). The lead-frame package comprising an integrated circuit substrate comprising at least a first surface and a second surface opposite the first surface. The integrated circuit substrate further comprising: a plurality of conductive leads providing a conductive path between the second surface and the first surface; a conductive trace formed within the integrated circuit substrate; and an integrated insulating layer forming the first surface of the integrated circuit substrate, the integrated insulating layer defining a plurality of conductive wirebond pads associated with the plurality of conductive leads and providing an electrical connection to the plurality of conductive leads. The lead-frame package further comprising an integrated circuit electrically isolated from the conductive trace by the integrated insulating layer, wherein the integrated circuit is positioned to determine an electromagnetic property of the conductive trace, and wherein the integrated circuit is electrically connected to the plurality of conductive leads. The electrical system further includes the PCB comprising a current carrying conductive path and a plurality of conductive contact surfaces, wherein the current carrying conductive path is configured to interface with the conductive trace by two or more of the plurality of conductive surfaces.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates an example lead-frame package comprising an integrated circuit configured to measure an electromagnetic property of an electrically insulated conductive trace.

FIG. 2 illustrates a top-level view of an example integrated circuit substrate and corresponding integrated circuit in accordance with an example embodiment of the present disclosure.

FIG. 3 illustrates a cross-section view of an example integrated circuit substrate and corresponding integrated circuit in accordance with an example embodiment of the present disclosure.

FIG. 4A – FIG. 4C illustrate perspective views of various layers of an example integrated circuit substrate in accordance with an example embodiment of the present disclosure.

FIG. 5 illustrates example wirebond connections of an integrated circuit within a lead-frame package in accordance with an example embodiment of the present disclosure.

FIG. 6 illustrates a cross-section view of an example lead-frame package in accordance with an example embodiment of the present disclosure.

FIG. 7 illustrates a cross-section view of an example integrated circuit substrate comprising reduced size conductive wirebond pads in accordance with an example embodiment of the present disclosure.

FIG. 8 illustrates a perspective view of an example integrated circuit substrate comprising reduced size conductive wirebond pads and corresponding integrated circuit in accordance with an example embodiment of the present disclosure.

FIG. 9A – FIG. 9B illustrate an integrated circuit substrate configured for an integrated circuit in a flip-chip configuration in accordance with an example embodiment of the present disclosure.

FIG. 10 illustrates an integrated circuit in a flip-chip configuration, positioned to measure an electromagnetic property of a curved narrowed trace in accordance with an example embodiment of the present disclosure.

FIG. 11 illustrates an embedded integrated circuit in accordance with an example embodiment of the present disclosure.

FIG. 12 illustrates an example electrical system providing electrical insulation to a driver die in accordance with an example embodiment of the present disclosure.

FIG. 13 depicts an example process for manufacturing a lead-frame package in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with electrically insulating an integrated circuit (IC) in a lead-frame package from one or more conductive components within the IC substrate of the lead-frame package. As understood by those of skill in the field to which the present disclosure pertains, there are numerous example scenarios in which an electrical component of an IC substrate may need to be electrically insulated from the IC housed within the lead-frame package.

Many electronic systems utilize PCBs to support and connect the various electrical components of an electrical system. A PCB may include a rigid structure with a plurality of mount regions configured to receive various electrical components. The PCB may further include conductive traces or paths to enable electrical connections between the various electrical components. A PCB may commonly receive surface-mounted and/or socketed electrical components, including various ICs.

In general, a lead-frame package is a surface-mount technology providing structural support for an IC, protection from environmental factors, and an electrical connection between the PCB and the IC without through holes. Conductive surfaces (leads) on the bottom surface of the lead-frame package are coupled with conductive surfaces on the surface of the PCB. The lead-frame package protects the electrical components and electrical connections of the IC from environmental factors ensuring reliability of the electrical system even in extreme conditions. Example lead-frame packages include quad-flat no-leads (QFN) packages and quad-flat no-leads multi-row (QFNmr) packages.

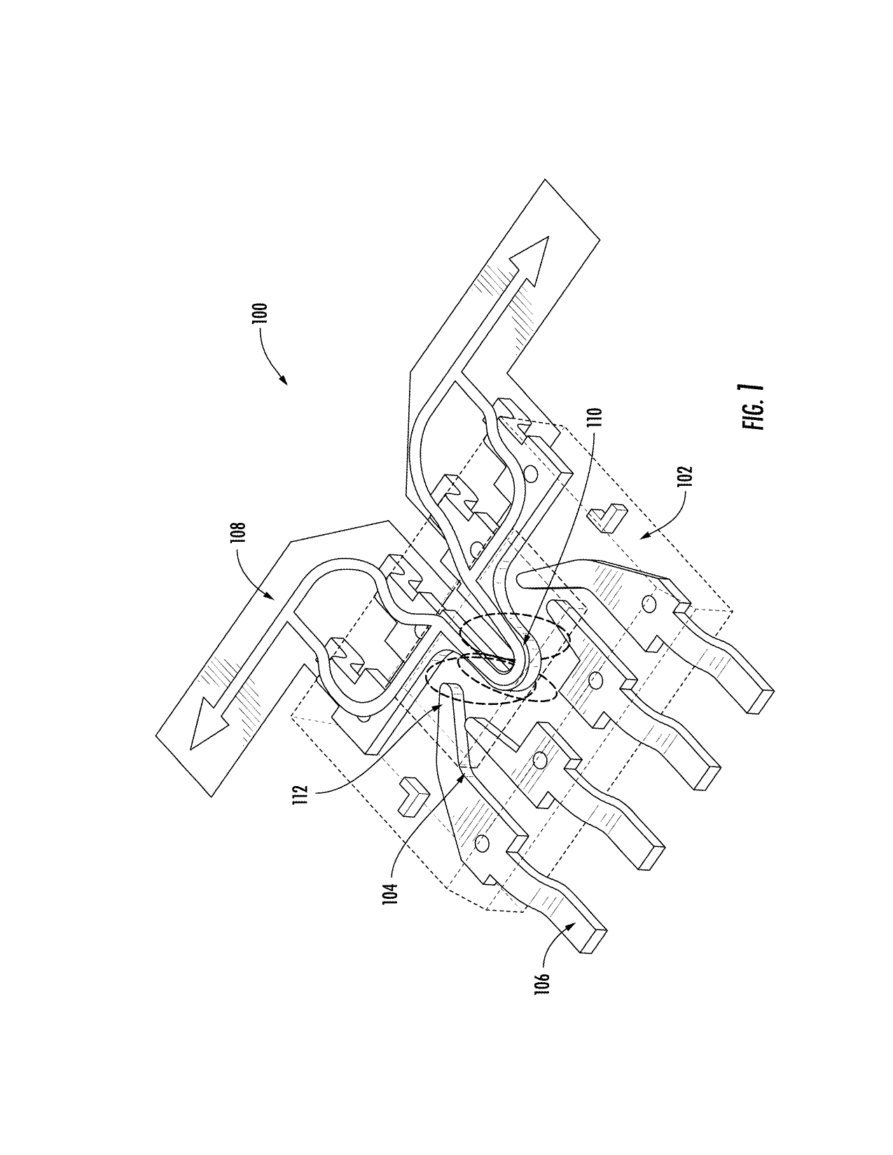

As depicted in FIG. 1, some lead-frame packages 100 include ICs 104 configured to determine the current flow through a conductive trace 108. As depicted in FIG. 1, the conductive trace 108 is electrically coupled with the example lead-frame package 100 by a plurality of conductive leads 106. The conductive leads 106 may direct the flow of current in the conductive trace 108 through a portion of the IC substrate 102 of the lead-frame package 100. For example, current may flow through the narrowed trace 110 within the IC substrate 102. The IC 104 is positioned proximate the narrowed trace 110 and configured to measure one or more electromagnetic properties of the narrowed trace 110. For example, the IC 104 may be configured to measure the magnetic field 112 near the narrowed trace 110 and determine the current through the conductive trace 108 based on the magnetic field 112.

As depicted in FIG. 1, in order to determine the current through the conductive trace 108 based on the magnetic field 112, the IC 104 must be electrically insulated from the conductive trace 108, including the narrowed trace 110, while still enabling measurement of the one or more electromagnetic properties of the narrowed trace 110. In some previous examples, glass or insulating tape have been placed on a surface of the lead-frame package 100 between the IC 104 and the narrowed trace 110. However, glass may be thick and expensive. The thickness of the glass may adversely effect the sensitivity of the current sensing IC 104. In addition, the thickness of the glass may increase the overall area occupied by the lead-frame package 100. Further, the cost of using glass as an electrically insulating medium may be prohibitively high. Insulating tape may crack and/or delaminate during operation of the IC 104. Cracking and/or delamination may create gaps between the narrowed trace 110 and the current sensing IC 104. Such gaps may cause leakage current, adversely affecting the ability of the IC 104 to accurately determine the electromagnetic properties of the narrowed trace 110.

The various example embodiments described herein provide an integrated insulating layer integrated as the top layer of the IC substrate of the lead-frame package. The integrated insulating layer is a dielectric material, compound, or insulating film that is applied during the manufacture of an IC substrate. The integrated insulating layer provides an electrically insulating layer between the IC 104 and the narrowed trace 110. An integrated insulating layer may be applied to the top surface of the IC substrate of a lead-frame package during manufacturing of the IC substrate. In addition, the integrated insulating layer enables conductive traces to pass through and/or along the integrated insulating layer. The integrated insulating layer provides necessary insulation between the IC of a lead-frame package an electronic component, such as a conductive trace 108/narrowed trace 110.

In some embodiments, vias and/or traces may be formed through and/or along the integrated insulating layer. Thus, conductive wirebond pads electrically connecting to the plurality of conductive leads of the lead-frame package may be formed providing a conductive path from the top surface of the IC substrate to the conductive leads. Conductive bond wires of the lead-frame package may connect the IC to the conductive wirebond pads, providing a conductive path from the IC to the conductive leads and external electrical components of the electrical system.

One such integrated insulating layer may comprise a dielectric buildup film. Dielectric buildup film is an insulating film that is applied during the manufacture of an IC substrate. The dielectric buildup film may be applied using a vacuum lamination and curing process. The vacuum lamination and curing process enables the dielectric buildup film to adhere to the IC substrate. In addition, vias and/or openings may be formed using laser drilling. Further, conductive paths may be formed by electroplating. In some embodiments, the dielectric buildup film may comprise anjinomoto build-up film (ABF).

As a result of the herein described example embodiments and in some examples, the integrated insulating layer is formed as an integrated part of the IC substrate. Because the integrated insulating layer is formed as an integrated part of the IC substrate, the integrated insulating layer does not delaminate, causing gaps between the narrowed trace and the IC. In addition, the integrated insulating layer may reduce the thickness and cost of an insulating layer when compared to a glass insulator. Eliminating gaps between the narrowed trace and the IC and reducing the space between the narrowed trace and the IC die, while still maintaining electrical insulation, enables higher sensitivities to current flowing through the narrowed trace at the IC. In addition, integrating the integrated insulating layer as the top layer of the IC substrate reduces the manufacturing complexity and cost of manufacturing.

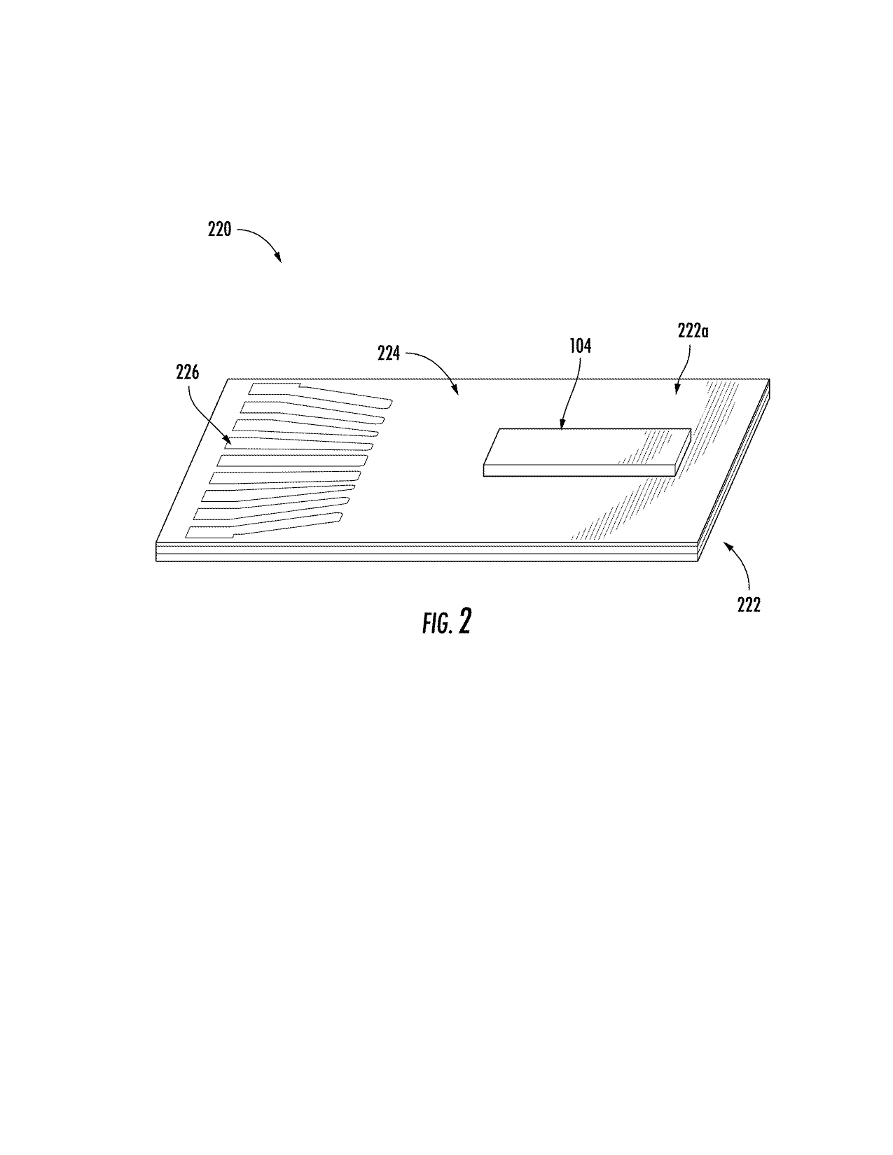

Referring now to FIG. 2, an example lead-frame package 220 is provided. As depicted in FIG. 2, the example lead-frame package 220 includes an IC 104 positioned on an IC substrate 222. The top surface 222a of the IC substrate 222 is formed by an integrated insulating layer 224. The IC substrate 222 further includes a plurality of conductive wirebond pads 226 formed in the surface of the integrated insulating layer 224.

As depicted in FIG. 2, the example lead-frame package 220 includes an IC 104. An IC 104 (e.g., IC die) is any block of semiconductor material utilizing circuitry and/or electrical components to perform one or more functions. An IC 104 may include a processor, reconfigurable fabric, passive electrical components, active electrical components, memory, communications circuitry, and/or any other electrical components necessary to perform the functionality of the IC 104. In one example embodiment, the IC 104 is configured to determine the current in a conductive component (e.g., narrowed trace 110 as depicted in FIG. 1) proximate the IC 104. In such an embodiment, the IC 104 is configured to measure one or more electromagnetic properties of the conductive component while electrically insulated from the conductive component. For example, the IC 104 may utilize the Hall effect to determine the current in the conductive component based on changes in the magnetic field proximate the conductive component.

An IC 104 is further configured to receive and/or generate one or more electrical signals. The one or more electrical signals are transmitted between the IC 104 and an electrical system through the one or more conductive leads (e.g., conductive leads 106 as depicted in FIG. 1). The IC 104 may electrically connect to the one or more conductive leads through the plurality of conductive wirebond pads 226. A conductive wirebond pad 226 is any conductive material at the top surface 222a of the IC substrate 222 providing a conductive path to the one or more conductive leads of the lead-frame package 220. An IC 104 may include a plurality of electrical contact points configured to interface with the one or more conductive wirebond pads 226. The IC 104 may be electrically connected to the conductive wirebond pads 226 via conductive bond wires.

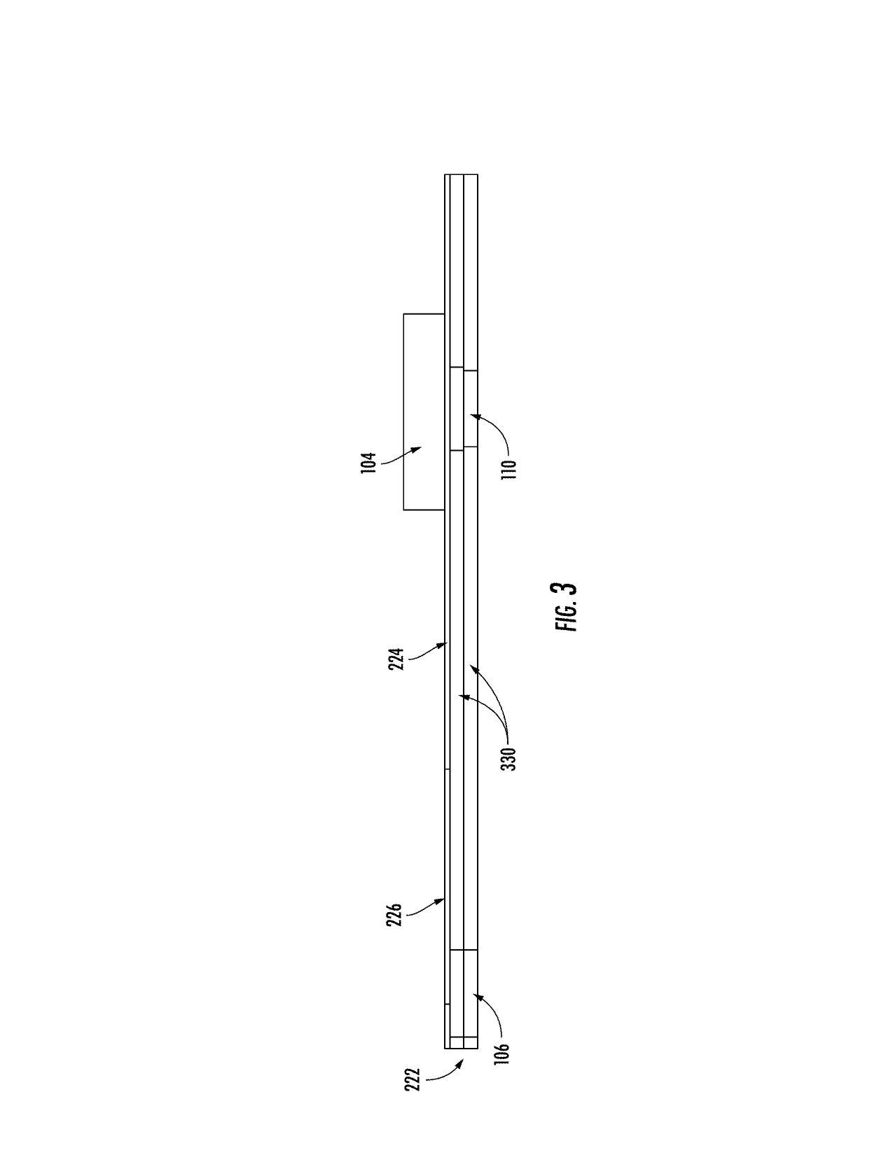

As further depicted in FIG. 2, the lead-frame package includes an IC substrate 222. The IC substrate 222 defines the interface between the IC 104 of the lead-frame package 220 and an underlying circuit board (e.g., printed circuit board). For example, the IC substrate 222 may define a plurality of conductive paths between the conductive leads and the one or more conductive wirebond pads 226. In some embodiments, the IC substrate 222 may define the conductive path of the current carrying conductive trace passing through the IC substrate 222. For example, the IC substrate 222 may define a narrowed trace proximate the IC 104 such that the IC 104 may determine the one or more electromagnetic properties of the conductive trace without electrical contact. In some embodiments, the IC substrate 222 may be formed using copper connection in molding (C2iM) processes or molded interconnect substrate (MIS) processes as further described in relation to FIG. 3.

As further depicted in FIG. 2, the top surface 222a of the IC substrate 222 is defined by an integrated insulating layer 224. An integrated insulating layer 224 is an insulating dielectric, compound, film, or other material that is applied as the top surface 222a of the IC substrate 222 during the manufacture of the IC substrate 222. The integrated insulating layer 224 provides an electrically insulating layer between the IC 104 and the narrowed trace 110. Insulating materials comprising the integrated insulating layer 224 may include any non-conductive material configured to insulate the various conductive paths of the IC substrate 222 from the IC 104. For example, a molding material, an epoxy, a resin, a polymer plastic, a dielectric buildup film, or other similar material. The integrated insulating layer 224 may be applied by any process utilized to manufacture the IC substrate 222, such as a copper connection in molding (C2iM) process, or a molded interconnect substrate (MIS) process.

In addition, the integrated insulating layer 224 enables conductive traces to pass through the integrated insulating layer 224 and/or conductive surfaces (e.g., conductive wirebond pads 226) to be defined on the integrated insulating layer 224. The integrated insulating layer 224 provides necessary insulation between the IC 104 of the lead-frame package 220 and any underlying electronic components, such as conductive trace 108/narrowed trace 110 as depicted in FIG. 1. Because the integrated insulating layer 224 is formed as an integrated part of the IC substrate 222, the integrated insulating layer 224 does not delaminate or cause gaps to be formed between the underlying conductive components and the IC 104.

In some embodiments, the integrated insulating layer 224 may comprise a dielectric buildup film. Dielectric buildup film is an insulating film that is applied to the top surface 222a of the IC substrate 222 during the manufacture of an IC substrate 222. The dielectric buildup film provides an electrically insulating layer between the IC 104 and the narrowed trace 110. The dielectric buildup film may be applied using a vacuum lamination and curing process. The vacuum lamination and curing process enables the dielectric buildup film to adhere to the IC substrate 222. In some embodiments, the dielectric buildup film comprises an anjinomoto build-up film (ABF). In some embodiments, the dielectric buildup film comprises a ShinEtsu buildup film.

Referring now to FIG. 3, a cross-section of an example IC substrate 222 and corresponding IC 104 is provided. As depicted in FIG. 3, the example IC substrate 222 comprises dielectric material 330 formed to insulate conductive paths (e.g., conductive lead 106, narrowed trace 110). As further depicted in FIG. 3, an integrated insulating layer 224 forms the top surface 222a of the IC substrate 222. A conductive wirebond pad 226 is formed in the integrated insulating layer 224 providing a conductive path from the top surface 222a of the IC substrate 222 to the conductive lead 106 at the bottom surface 222b of the IC substrate 222. In addition, an IC 104 is positioned on the integrated insulating layer 224 of the IC substrate 222 and positioned above the current carrying narrowed trace 110 formed below the integrated insulating layer 224 of the IC substrate 222.

As depicted in FIG. 3, the IC substrate 222 comprises layers of dielectric materials 330 electrically insulating conductive paths. Dielectric materials 330 comprise any non-conductive material configured to provide structure to an IC substrate 222 and insulate the various conductive paths passing through the IC substrate 222. The dielectric materials 330 may an epoxy, a resin, a polymer plastic, or other similar material.

In some embodiments, the IC substrate 222 and integrated insulating layer 224 may be formed using a copper connection in molding process (C2iM). In such an embodiment, the dielectric materials 330 comprise an epoxy molding compound without glass fibers. The IC substrate 222 may be formed in layers comprising dielectric material 330 and/or interconnected conductive material. For example, a conductive material may be placed on a metal carrier plating. The conductive material may then be encapsulated with a dielectric material 330 (molding). The dielectric material 330 may then be ground to expose portions of the layer of dielectric material 330. Such steps may be repeated, forming interconnected paths of conductive material between layers. As depicted in FIG. 3, the conductive path from the conductive leads 106 to the conductive wirebond pads 226 may be formed by interconnecting each layer of dielectric material 330 in a continuous path.

In some embodiments, the IC substrate 222 and integrated insulating layer 224 may be formed using a molded interconnect substrate (MIS) process. An MIS process may consist of forming an IC substrate 222 using a pre-molded structure with one or more layers. Each layer is pre-configured with copper plating or interconnects to provide electrical connections (e.g., conductive lead 106, narrowed trace 110) within the package. Each layer is then encapsulated with a dielectric material 330 (molding). The dielectric material 330 may then be etched to expose portions of the layer of dielectric material 330. Such steps may be repeated, to form interconnected paths of conductive material between layers of the IC substrate 220.

As further depicted in FIG. 3, an integrated insulating layer 224 is formed as the top surface of the IC substrate 222. The integrated insulating layer 224 provides an insulating layer between the IC 104 and the underlying narrowed trace 110. The thickness of the integrated insulating layer 224 may affect the insulation properties of the integrated insulating layer 224. For example, a thicker integrated insulating layer 224 may provide insulation at higher voltages. However, the thickness of the integrated insulating layer 224 also affects the sensitivity of the current measurement performed by the IC 104 because of the separation between the narrowed trace 110 and the IC 104. For example, a thicker integrated insulating layer 224 may reduce the sensitivity of the current measurement at the IC 104. In embodiments comprising a dielectric buildup film as the integrated insulating layer 224, the integrated insulating layer 224 is between 40 micrometers and 60 micrometers thick; more preferably between 45 micrometers and 55 micrometers thick; most preferably between 48 and 52 micrometers thick. A thicker integrated insulating layer 224 may provide electrical insulation at higher voltages.

An in instance in which the integrated insulating layer 224 comprises a dielectric buildup film, the dielectric buildup film may be attached to the surface of the IC substrate 222 using lamination process, for example, vacuum lamination. Once attached, conductive paths may be continued and/or completed by laser drilling openings or paths and then filling the openings or paths with conductive materials using electroplating. Such a process may be utilized to form conductive wirebond pads 226 in the surface of the dielectric buildup film.

As further depicted in FIG. 3, the IC 104 is positioned proximate the narrowed trace 110 opposite the integrated insulating layer 224. In some embodiments, the IC 104 may be configured to measure the current passing through the narrowed trace 110 based on one or more electromagnetic properties measured by the IC 104. As such, the IC 104 is placed in close proximity to the narrowed trace 110. For example, as shown in FIG. 3, the narrowed trace 110 is within the projection of the outer perimeter of the IC 104 relative to the top surface 222a of the IC substrate 222 in at least one direction. In addition, the narrowed trace 110 is in contact with a surface of the integrated insulating layer 224 exactly opposite the IC 104.

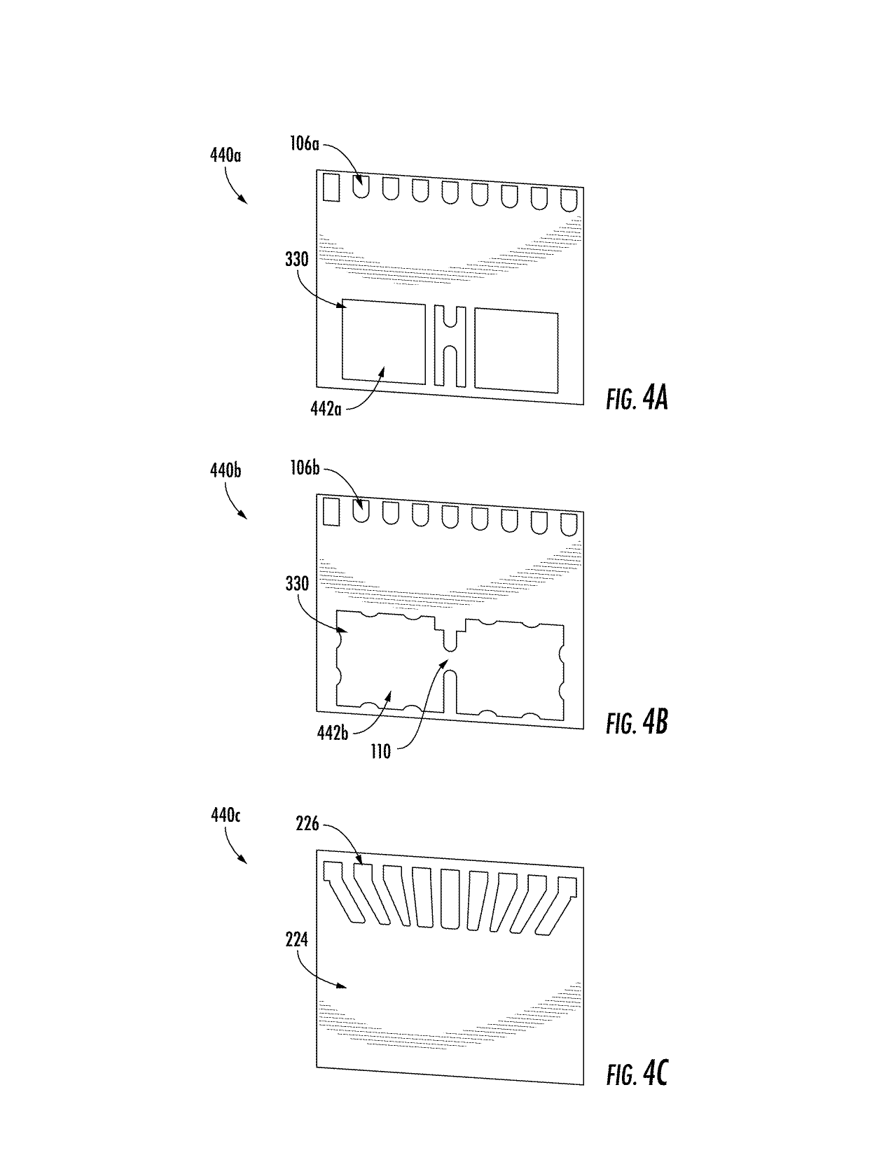

Referring now to FIG. 4A – FIG. 4B, example layers: first layer 440a, second layer 440b, and third layer 440c of an example IC substrate are provided.

As depicted in FIG. 4A, the first layer 440a of the IC substrate includes a plurality of conductive leads 106a and a conductive trace 442a defined within the dielectric material 330. The plurality of conductive leads 106a provide a conductive path between the IC of the lead-frame package and an underlying circuit board. The conductive leads 106a enable the transmission and reception of electrical signals between the IC and various electrical components interconnected by an underlying circuit board.

The conductive trace 442a is also configured to interface with the underlying circuit board. In one non-limiting example, the conductive trace 442a may be configured to interface with a current carrying conductive wire. The conductive trace 442a may enable the transmission of the current through the IC substrate of the lead-frame package such that an IC may determine the current flowing through the current carrying conductive wire based on one or more electromagnetic properties measured by the IC.

As depicted in FIG. 4B, the second layer 440b is positioned in physical contact with the first layer 440a. The second layer 440b is positioned such that the conductive leads 106a of the first layer 440a are in electrical contact with the conductive leads 106b of the second layer 440b. In addition, the conductive trace 442a of the first layer 440a is in electrical contact with the conductive trace 442b of the second layer 440b. The conductive portions of the second layer 440b further form a narrowed trace 110 of the conductive trace 442b. The narrowed trace 110 has a smaller cross-sectional area than the conductive trace 442a/442b. Thus, the current flowing through the conductive trace 442a/442b is forced through the narrowed trace 110. Forcing the current to pass through the narrowed trace 110 may enable more accurate determinations of the electromagnetic properties by the IC.

As depicted in FIG. 4C, the third layer 440c includes an integrated insulating layer 224 substantially covering the surface of the third layer 440c. In addition, a plurality of conductive wirebond pads 226 are formed in the integrated insulating layer 224 corresponding with the conductive leads 106a/106b of the first layer 440a and second layer 440b. The third layer 440c is positioned in physical contact with the second layer 440b on a surface of the second layer 440b opposite the first layer 440a. The third layer 440c is positioned such that the conductive leads 106b of the second layer 440b are in electrical contact with the conductive wirebond pads 226 of the third layer 440c. The integrated insulating layer 224 provides electrical insulation between the top surface of the third layer 440c and the underlying narrowed trace 110 and conductive trace 442a/442b. In addition, the conductive wirebond pads 226 provide an electrical connection between the IC and external electrical components through the conductive leads 106a/1106b.

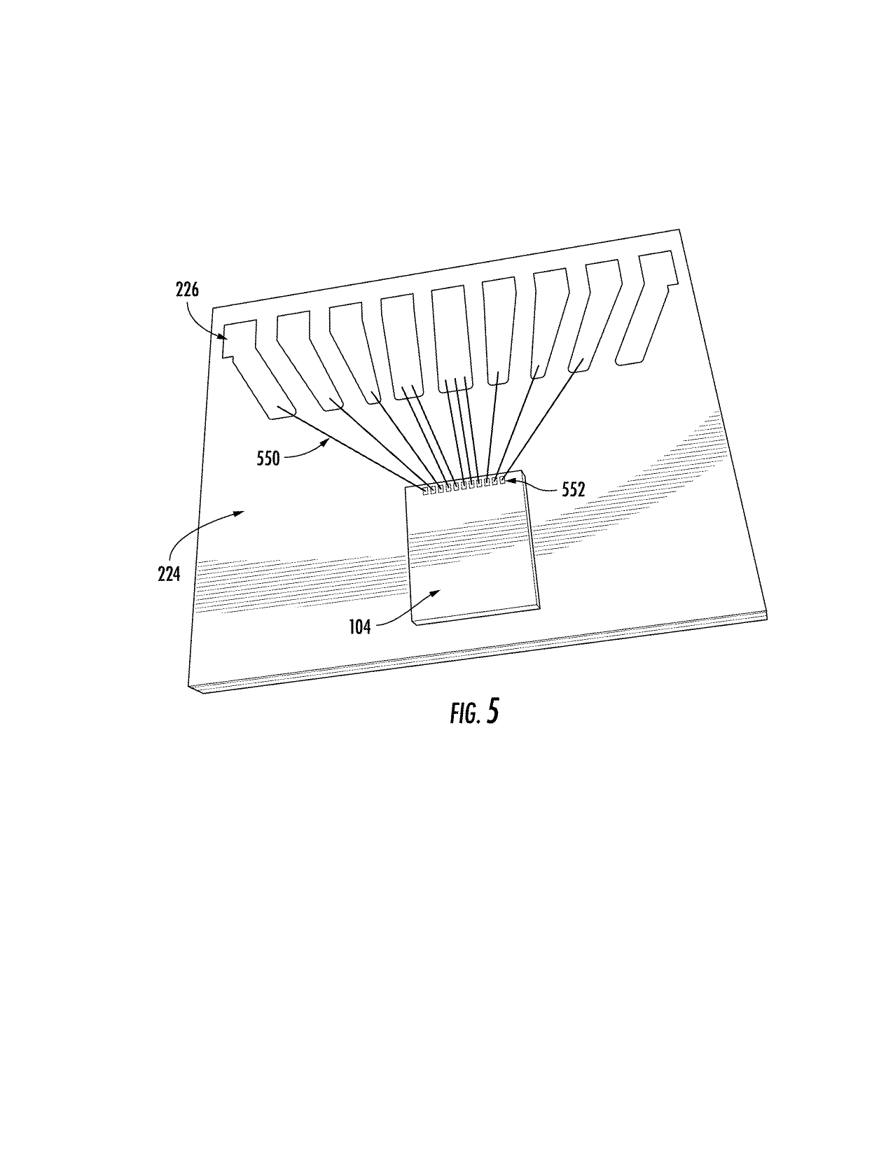

Referring now to FIG. 5, example conductive bond wires 550 providing an electrical connection between the plurality of conductive wirebond pads 226 and the electrical contact points 552 on the IC 104 is provided. As further depicted in FIG. 5, the integrated insulating layer 224 provides an insulating barrier between the IC 104 and underlying electrical components.

As depicted in FIG. 5, the conductive bond wires 550 providing an electrical connection between the plurality of conductive wirebond pads 226 and the electrical contact points 552 on the IC 104. A conductive bond wire 550 is any electrically conductive material forming a conductive path from a conductive lead via a conductive wirebond pad 226 to an electrical contact point 552 of the IC 104. The conductive bond wire 550 facilitates the transmission of electrical signals between the IC 104 and the conductive leads, providing an electrical connection to an external electrical system. Conductive bond wires 550 may comprise aluminum, copper, silver, gold, or other similar conductive materials. In some embodiments, a conductive bond wire 550 may be attached using a ball bonding technique, or a wedge bonding technique.

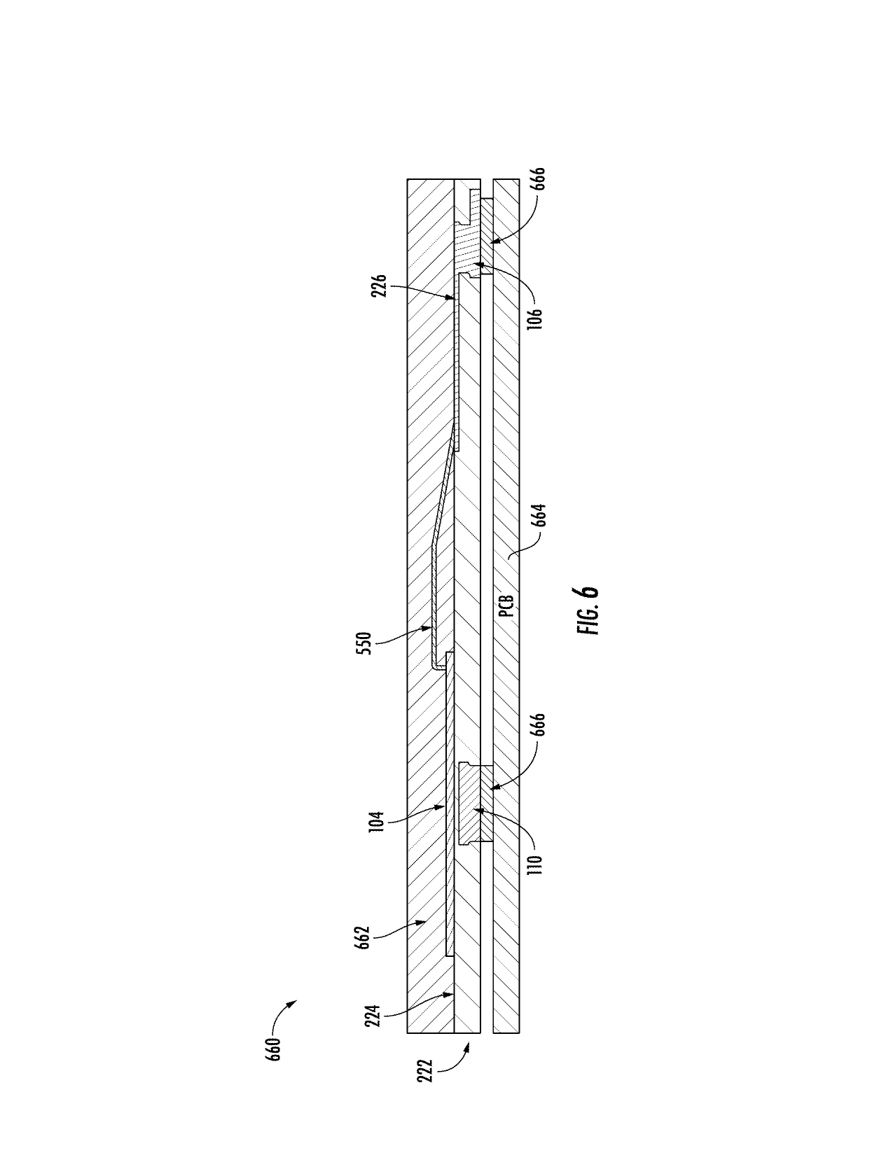

Referring now to FIG. 6, an example lead-frame package 660 is provided. As depicted in FIG. 6, the example lead-frame package 660 includes an IC substrate 222 comprising a narrowed trace 110 and conductive lead 106. The top surface of the IC substrate 222 is defined by an integrated insulating layer 224 forming an insulating layer between the IC 104 and the narrowed trace 110. The integrated insulating layer 224 further defines a conductive wirebond pad 226 forming a conductive path between the top surface of the IC substrate 222 and the conductive lead 106. A conductive bond wire 550 provides an electrical connection between the IC 104 and the conductive lead 106. As further depicted in FIG. 6, the IC 104 and conductive bond wire 550 are encased in a package molding 662. The conductive paths (e.g., narrowed trace 110, conductive lead 106) are attached to a printed circuit board (PCB) 664 by a conductive bond 666.

As depicted in FIG. 6, the example lead-frame package 660 includes a package molding 662. The package molding 662 comprises any non-conductive material configured to protect the IC 104 within the lead-frame package 660 from a surrounding environment. For example, in some embodiments, an IC 104 may be on an electrical system in a harsh environment (e.g., high temperatures, low temperatures, exposed to dirt, water, dust, sand, etc.). A lead-frame package 660 may be utilized to protect the IC 104 in a portion of an automobile (e.g., engine, chassis, driveline, etc.). As depicted in FIG. 6, the package molding 662 is formed to define the outer bounds of the lead-frame package 660. The package molding 662 may comprise a resin, polymer plastic, or other insulating material.

As further depicted in FIG. 6, the example lead-frame package 660 is electrically coupled to a PCB 664 by conductive bonds 666. A PCB 664 is a structure comprising laminated layers of conductive and insulating material, providing rigid structure and electrical connections between various electrical components (e.g., lead-frame package 660) of a circuit. A PCB 664 may utilize copper or a similar conductor to form electrical paths between the electrical components comprising a circuit. The conductive layers may be accompanied by one or more insulating layers. Insulating layers may be comprised of an insulating material, such as fiberglass. A PCB 664 may enable the integration of one or more electrical components by surface mount technologies. Surface mount technologies provide for attaching electrical components directly to the surface of a PCB 664. Surface mount technologies enable increased automation in the manufacture of circuits utilizing a PCB 664. In addition, surface mount technologies reduce cost and improve the quality and reliability of the circuit.

A PCB 664 may include a plurality of conductive surfaces configured to interface with the conductive leads 106 of a lead-frame package 660. A conductive surface may be configured to provide an electrical connection to one or more electrical paths on the PCB 664. A conductive surface may comprise copper or another similar conductive material. The conductive surface may be configured to align with the conductive leads 106 of a lead-frame package 660. A conductive bond 666 such as solder, may be utilized to attach the conductive leads 106 of the lead-frame package 660 to the conductive surfaces of the PCB 664.

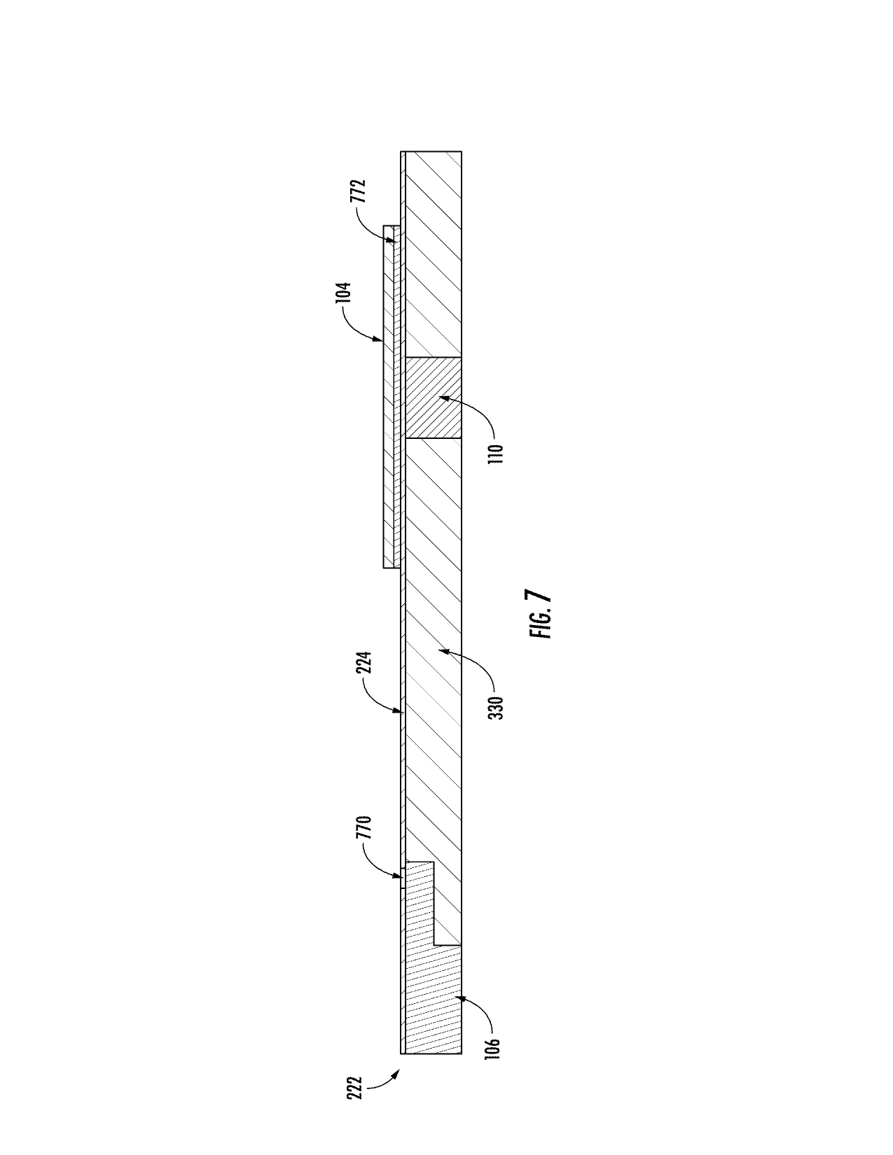

Referring now to FIG. 7, a cross sectional view of an example IC substrate 222 and corresponding IC 104 is provided. As depicted in FIG. 7, the example IC substrate 222 includes dielectric material 330 separating a conductive lead 106 and a narrowed trace 110. The top layer of the IC substrate 222 is defined by an integrated insulating layer 224 forming a conductive wirebond pad 770. The IC 104 is attached to the IC substrate 222 by a die attach film 772. As depicted in FIG. 7, the IC 104 is electrically separated from the narrowed trace 110 by the integrated insulating layer 224.

As depicted in FIG. 7, the conductive wirebond pad 770 formed by the integrated insulating layer 224 is reduced in size compared to the conductive wirebond pad 226. A reduced size conductive wirebond pad 770 may provide better isolation between the IC 104 and the underlying electrical components because less conductive material is exposed. The reduced size conductive wirebond pad 770 may further provide cost savings because less conductive material is necessary on the top surface of the IC substrate 222. However, reduced size conductive wirebond pads 770 may require longer conductive bond wires to reach the conductive surface provided by the conductive wirebond pad 770. In some embodiments, the size of the conductive wirebond pad 770 may be reduced such that the surface area exposed at the surface of the integrated insulating layer 224 is minimized. For example, in an instance in which gold wire having a 0.8 millimeter diameter is utilized as the conductive lead 106, a conductive wirebond pad 770 100 micrometers by 80 micrometers may be used.

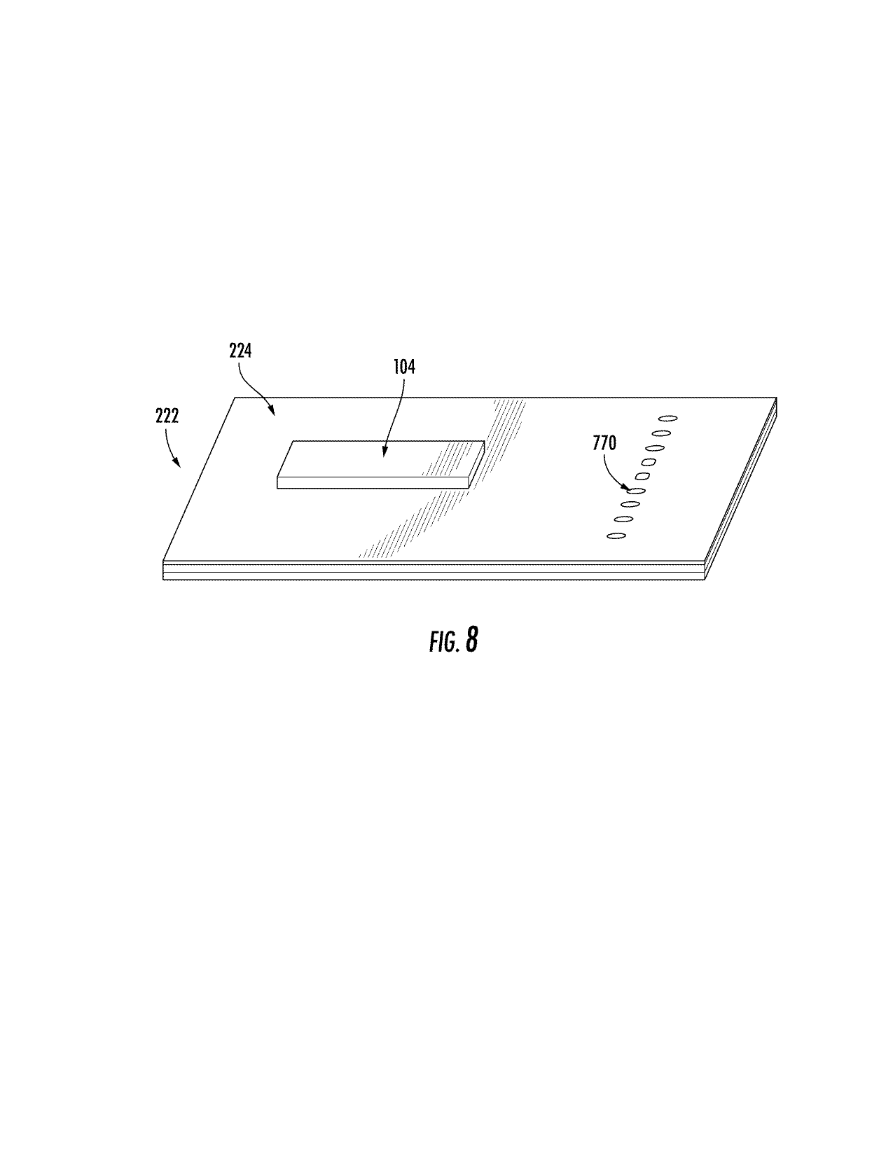

Referring now to FIG. 8, a perspective view of an example IC substrate 222 with reduced size conductive wirebond pads 770 and corresponding IC 104 is provided. As depicted in FIG. 7, the top layer of the IC substrate 222 is defined by an integrated insulating layer 224 forming a plurality of reduced size conductive wirebond pads 770. The reduced size conductive wirebond pads 770 provide more substantial isolation between the conductive portions of the IC substrate 222 and the IC 104. In addition, the reduced size conductive wirebond pads 770 reduce the amount of conductive material required at the integrated insulating layer 224. However, longer conductive bond wires may be required to reach the conductive surface provided by the conductive wirebond pads 770.

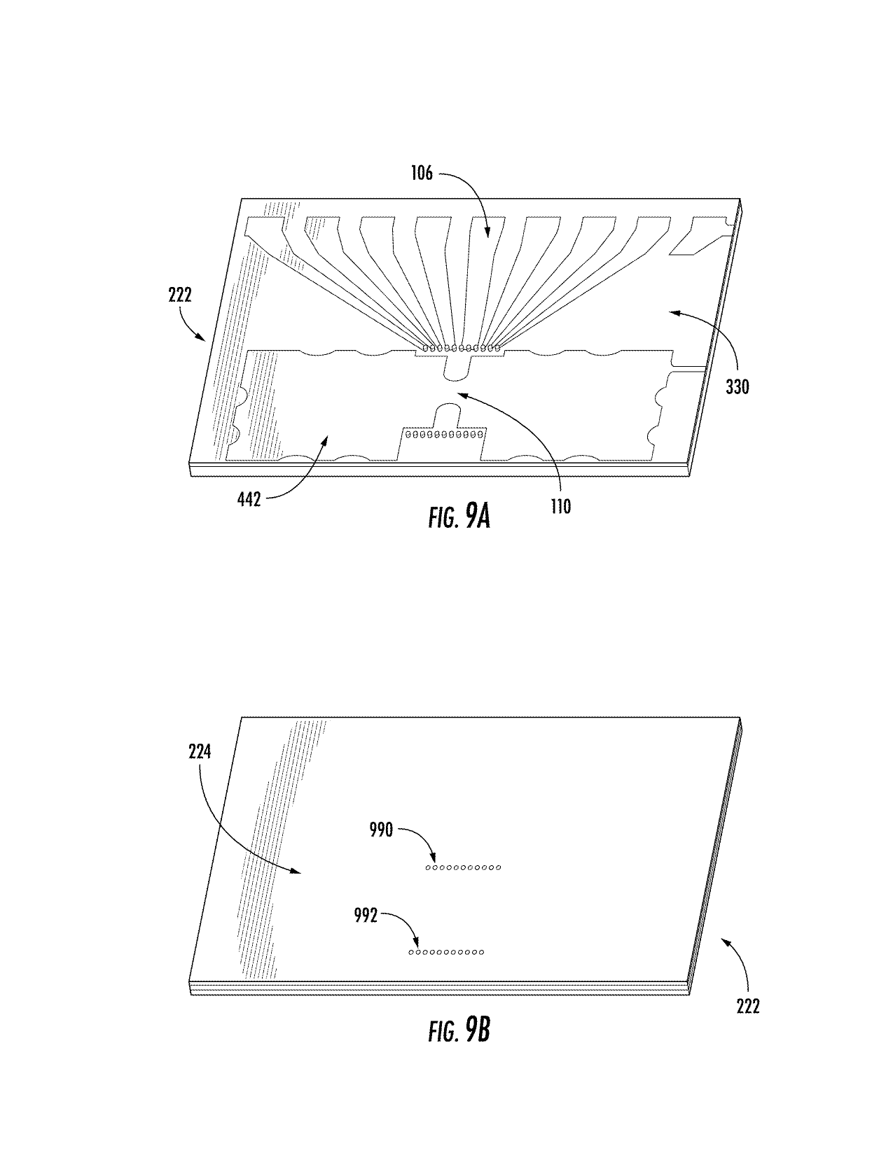

Referring now to FIG. 9A – FIG. 9B, an example IC substrate 222 designed to support an IC in a flip-chip configuration is provided. FIG. 9A depicts the layer of the IC substrate 222 below the integrated insulating layer 224. As depicted in FIG. 9A, the conductive leads 106 of the example IC substrate 222 are moved to align with the electrical contact points of an IC in a flip-chip configuration. As further depicted in FIG. 9A, the conductive trace 442, including a narrowed trace 110, are further defined in the dielectric material 330.

FIG. 9B depicts the top layer of the example IC substrate 222 designed to support an IC in a flip-chip configuration. As depicted in FIG. 9B, the integrated insulating layer 224 defines the top layer of the IC substrate 222, providing an electrically insulated layer between the conductive trace 444/narrowed trace 110, and the IC positioned on the integrated insulating layer 224. As further depicted in FIG. 9B, the integrated insulating layer 224 defines a plurality of conductive pads 990 configured to align with the conductive leads 106 depicted in FIG. 9A, and the electrical contact points on an IC in a flip-chip configuration.

An IC in flip-chip configuration is flipped upside down, such that the electrical contact points on the top of the IC are placed in contact with the integrated insulating layer 224. In some embodiments, an IC in flip-chip configuration may provide more accurate readings with regard to the electromagnetic properties of the conductive trace 442. For example, the sensing elements of an IC may be in closer proximity to the conductive trace 442 and narrowed trace 110 in an instance in which the IC is in a flip-chip configuration.

As further depicted in FIG. 9B, in some embodiments, the IC substrate 222 may further include adhesive connectors 992. Adhesive connectors 992 comprise any contact points between the IC substrate 222 and an IC providing structural stability to the IC, particularly in a flip-chip configuration. As depicted in FIG. 9B, in some embodiments, conductive pads 990 may only positioned on a side of an IC. Adhesive connectors 992 may be positioned at various points of the IC to stabilize the connection between the IC substrate 222 and an IC. Adhesive connectors 992 may comprise solder, glue, or any other adhesive configured to attach a portion of an IC to the IC substrate 222.

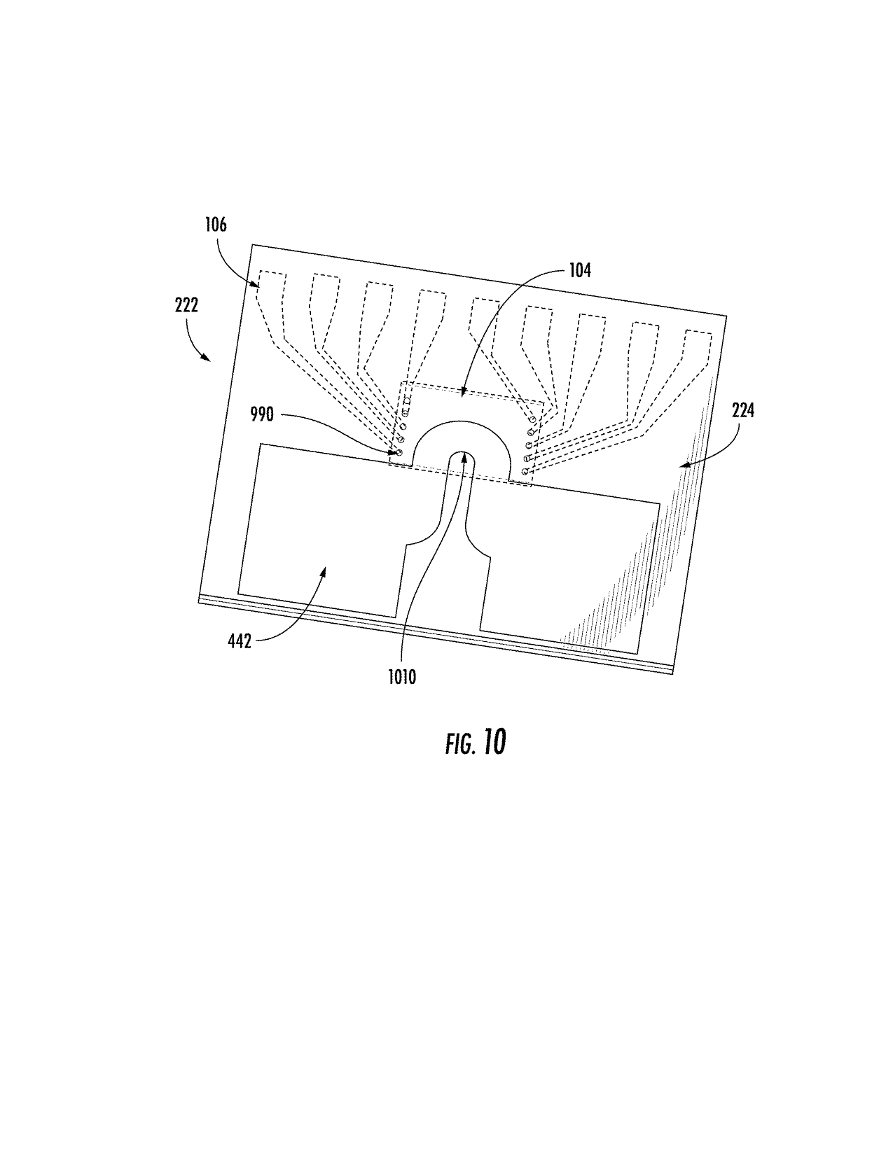

Referring now to FIG. 10, a perspective view of an example IC substrate 222 comprising a curved narrowed trace 1010 is depicted. As depicted in FIG. 10, the integrated insulating layer 224, the conductive leads 106, and IC 104 are all transparent, revealing the layer of the IC substrate 222 below the integrated insulating layer 224. The IC substrate 222 comprises a conductive trace 442 including a curved narrowed trace 1010 positioned within a projection of the outer perimeter of the IC 104. The IC substrate 222 further includes a plurality of conductive leads 106 terminating at the top surface of the IC substrate 222 at a plurality of conductive pads 990.

As depicted in FIG. 10, the example IC substrate 222 includes a plurality of conductive leads 106. The conductive leads 106 are designed for an IC 104 in flip-chip configuration. For example, a conductive path is defined in the IC substrate 222 such that the terminal ends of the conductive leads 106 terminate at conductive pads 990 aligned with the electrical contact points of an IC 104.

As further depicted in FIG. 10, the conductive trace 442 comprises a curved narrowed trace 1010. The curved narrowed trace 1010 is designed to concentrate the current flow through the conductive trace 442 in a conductive portion having a smaller cross-sectional area. By limiting the flow of current through the conductive trace 442 to a conductive portion having a smaller cross-sectional area, the flow of current may be brought in closer proximity to the sensing elements of the IC 104. In addition, by curving the curved narrowed trace 1010, the narrowed portion of the conductive trace 442 may be isolated within a projection of the outer perimeter of the IC 104 on the IC substrate 222. By isolating and narrowing the curved narrowed trace 1010 of the conductive trace 442, the current passing through the conductive trace 442 is concentrated near the active area of the IC 104. Concentrating the current near the accurate area may generate more accurate measurements of the electromagnetic properties of the conductive trace 442.

Although transparent in FIG. 10, the integrated insulating layer 224 provides electrical insulation between the curved narrowed trace 1010 of the IC substrate 222 and the IC 104.

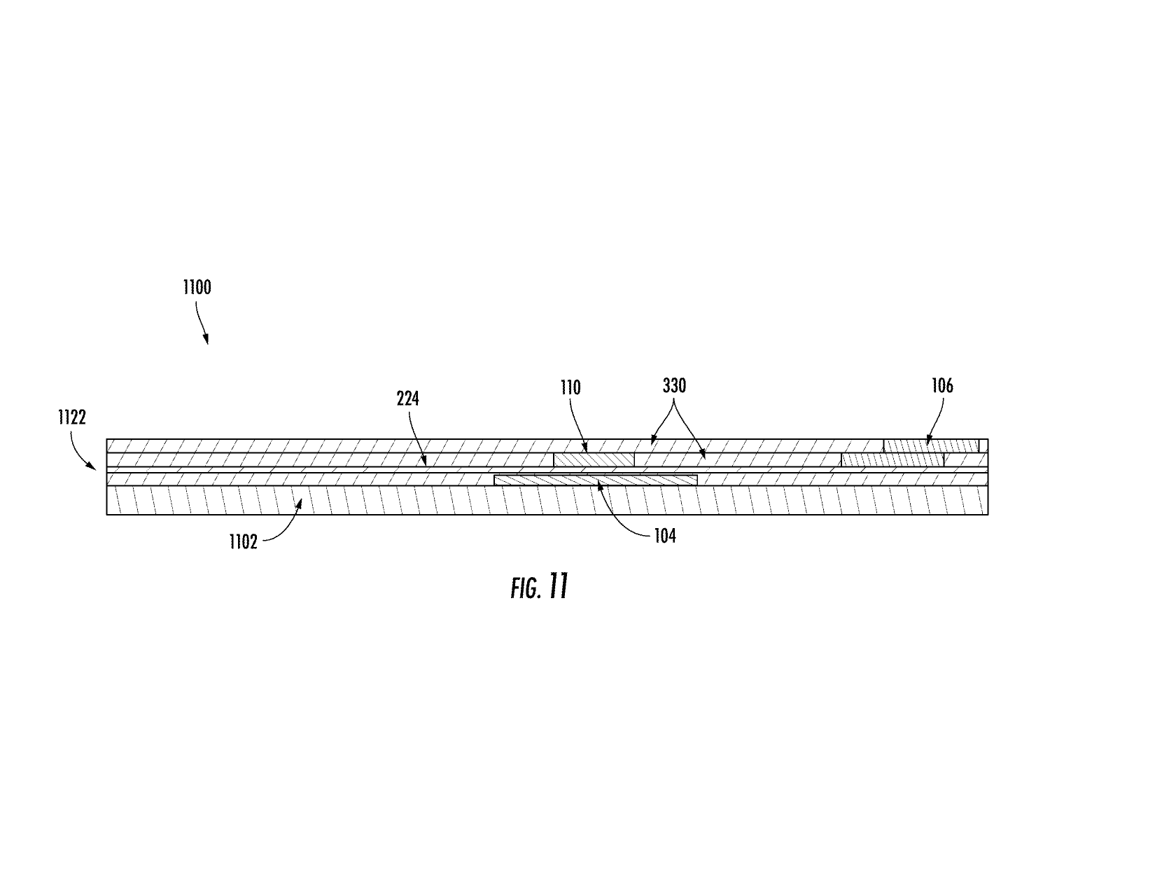

Referring now to FIG. 11, an example embodiment of a lead-frame package 1100 in which the IC 104 is embedded between the IC substrate 1122 and panel material 1102 (e.g., molding compound), is provided. As depicted in FIG. 11, the example IC substrate 1122 comprises an IC 104 positioned on a panel material 1102. The example IC substrate 1122 further includes an integrated insulating layer 224 covering the IC 104 and providing an insulating layer between the IC 104 and the narrowed trace 110. The IC substrate 1122 includes dielectric material 330 insulating the conductive paths (e.g., conductive trace 108, conductive trace 442, narrowed trace 110) within the IC substrate 1122.

Panel level package technology may be utilized to manufacture a lead-frame package 1100 such as depicted in FIG. 11. Panel level package technology enables the simultaneous manufacture of a plurality of lead-frame packages 1100. As depicted in FIG. 11, a plurality of ICs 104 may be positioned on a panel material 1102, or molding compound. Subsequently, the integrated insulating layer 224 may be positioned on top of the IC 104 forming an electrically insulating barrier. Conductive paths (e.g., conductive trace 108, conductive trace 442, narrowed trace 110) may be formed through the IC substrate 1122 with one or more conductive paths terminating at a conductive pad on the top surface of the lead-frame package 1100. Once manufactured, the lead-frame package 1100 with embedded IC 104 may experience a singulation process in which the individual lead-frame packages 1100 are separated.

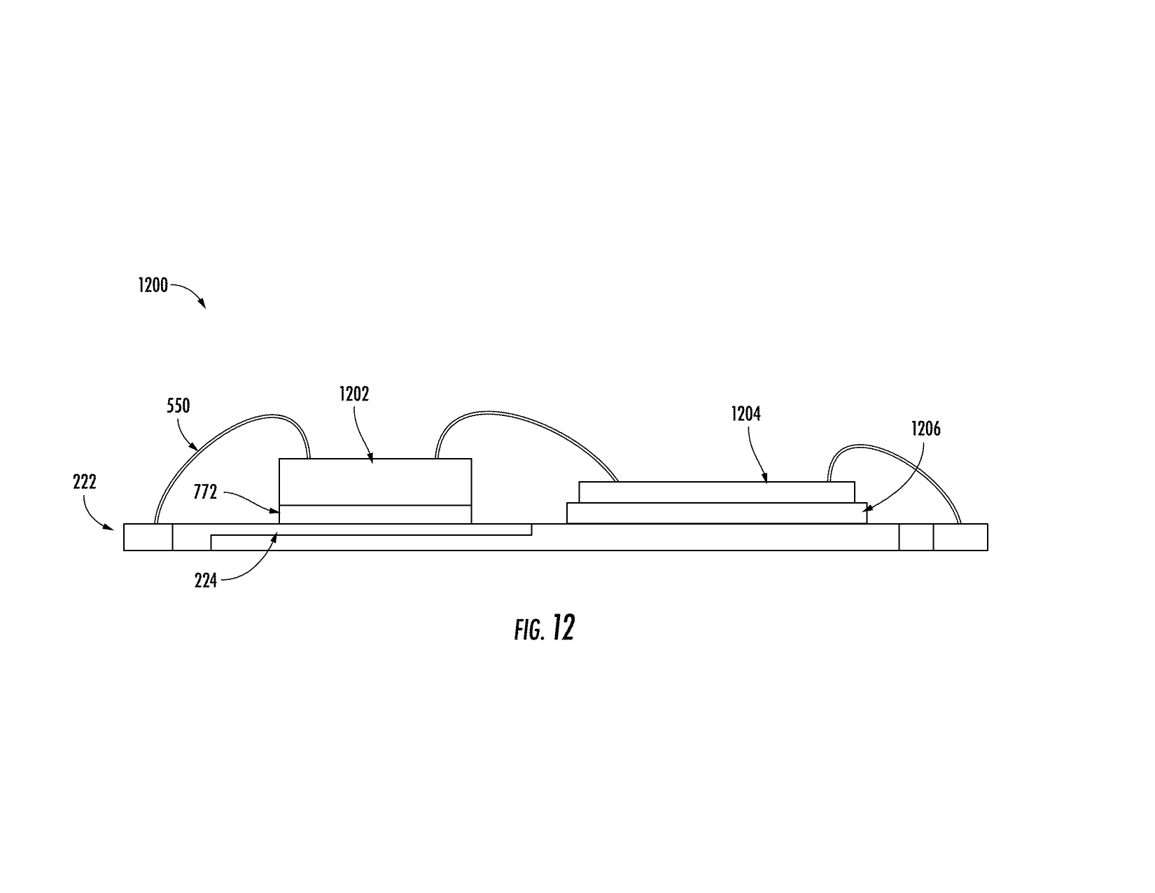

Referring now to FIG. 12, an additional embodiment of a lead-frame package 1200 in accordance with an example embodiment of the present disclosure is provided. As depicted in FIG. 12, the example lead-frame package 1200 includes a driver die 1202 and a power die 1204. The driver die 1202 is attached to an IC substrate 222 by a die attach film 772. The power die 1204 is attached to the IC substrate 222 by a hybrid glue 1206. In addition, the top layer of the IC substrate 222 in contact with the driver die 1202 comprises an integrated insulating layer 224.

As depicted in FIG. 12, in some embodiments, it may be desired to electrically insulate a portion of the IC substrate 222, for example, the portion of the IC substrate 222 proximate the driver die 1202. In such an embodiment, a portion of the top surface of the IC substrate 222 may be defined by the integrated insulating layer 224. In such an instance, the integrated insulating layer 224 provides electrical insulation between the driver die 1202 and the underlying layers of the IC substrate 222. Insulating the driver die 1202 from the power die 1204 precents electrical shorts from occurring between the high current power die 1204 and the lower current driver die 1202.

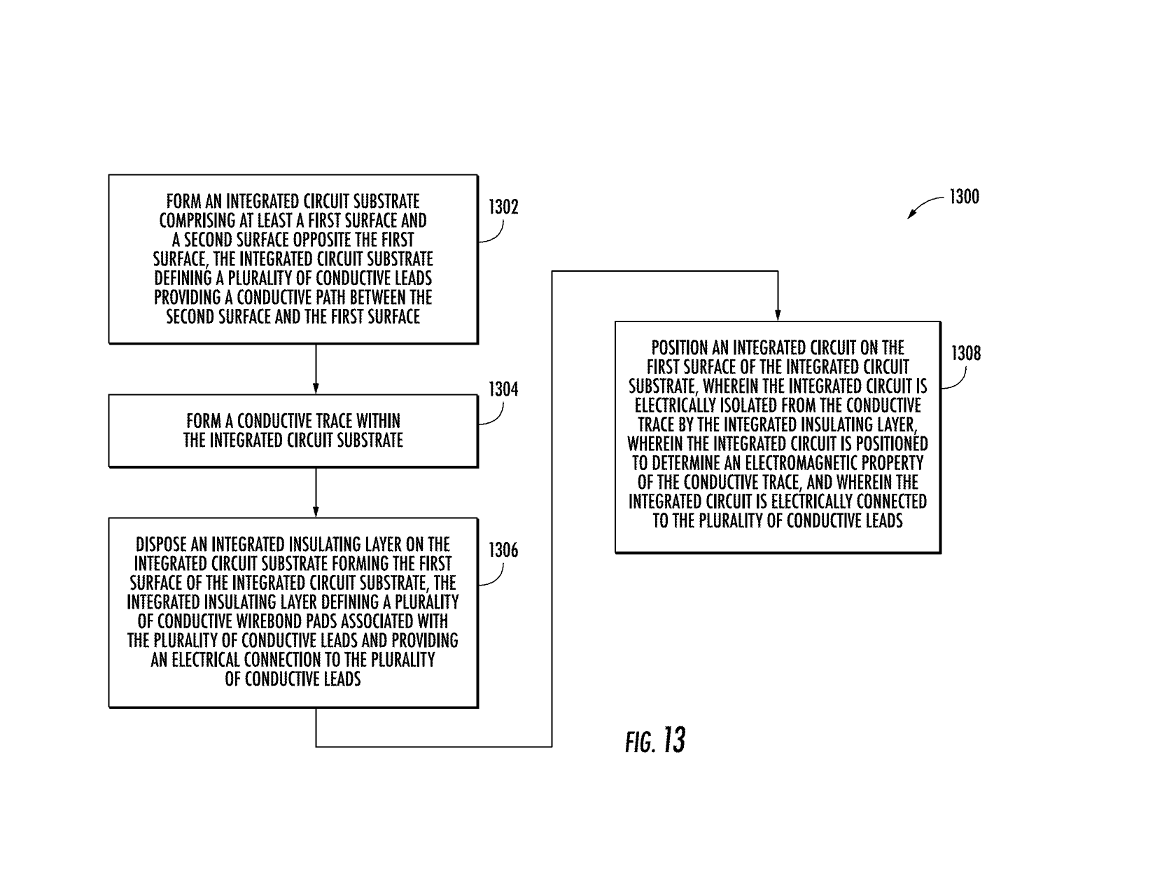

Referring now to FIG. 13, an example process 1300 for manufacturing a lead-frame package in accordance with an example embodiment of the present disclosure is provided. At block 1302, an integrated circuit substrate (e.g., IC substrate 222) is formed comprising at least a first surface (e.g., top surface 222a) and a second surface (e.g., bottom surface 222b) opposite the first surface, the integrated circuit substrate defining a plurality of conductive leads (e.g., conductive leads 106) providing a conductive path between the second surface and the first surface.

An IC substrate may comprise dielectric materials defining conductive paths between the conductive leads and the first surface of the IC substrate. Such conductive paths may provide an electrical connection from the first surface of the IC substrate to external electrical components, systems, processors, and so on by interfacing with the conductive leads. For example, a PCB may include corresponding conductive surfaces positioned to align with the conductive leads of the IC substrate. By coupling the conductive leads with the conductive surfaces of a PCB, electrical signals may be transmitted to and from electrical components interconnected with the PCB.

At block 1304, a conductive trace (e.g., conductive trace 442, narrowed trace 110, curved narrowed trace 1010) is formed within the integrated circuit substrate. The conductive trace may interface with a PCB or other circuitry through one or more conductive leads and corresponding conductive surfaces. A conductive trace may include a narrowed portion within the IC substrate. The narrowed portion comprises a smaller cross-sectional area of the conductive trace. For example, the narrowed portion may comprise only upper layers of the IC substrate. The narrowed portion may be configured to concentrate the flow of current in a portion of the IC substrate, for example, to enable detection of one or more electromagnetic properties of the conductive trace.

At block 1306, an integrated insulating layer (e.g., integrated insulating layer 224) is disposed on the integrated circuit substrate forming the first surface of the integrated circuit substrate, the integrated insulating layer defining a plurality of conductive wirebond pads (e.g., conductive wirebond pads 226) associated with the plurality of conductive leads and providing an electrical connection to the plurality of conductive leads. The integrated insulating layer comprises an insulating material, dielectric compound, and/or dielectric buildup film applied to the top surface of the IC substrate during the manufacture of the IC substrate. The integrated insulating layer provides an electrically insulating layer to the IC substrate, including the conductive paths within the IC substrate (e.g., the narrowed trace). In addition, conductive wirebond pads (e.g., conductive wirebond pads 226) are defined on the integrated insulating layer to enable an electrical connection with one or more conductive leads. Because the integrated insulating layer is formed as an integrated part of the IC substrate, the integrated insulating layer does not delaminate or cause gaps to be formed between the underlying conductive components and the IC of a lead-frame package. In some embodiments, the integrated insulating layer comprises a dielectric buildup film such as an anjinomoto build-up film (ABF) or ShinEtsu buildup film.

At block 1308, an integrated circuit (e.g., IC 104) is positioned on the first surface of the integrated circuit substrate, wherein the integrated circuit is electrically isolated from the conductive trace by the integrated insulating layer, wherein the integrated circuit is positioned to determine an electromagnetic property of the conductive trace, and wherein the integrated circuit is electrically connected to the plurality of conductive leads.

As described herein, the integrated insulating layer may define one or more conductive wirebond pads providing an electrical connection between the top surface of the IC substrate and the one or more conductive leads exposed at the bottom surface of the IC substrate. A lead-frame package includes electrical connections between electrical contact points on the IC and the conductive wirebond pads. In some embodiments, conductive bond wires may form the electrical connection between the IC and the conductive wirebond pads. In some embodiments, the integrated insulating layer may define conductive pads at or near the perimeter of the IC, enabling the IC to be attached to the conductive pads in a flip-chip configuration. The integrated insulating layer further provides electrical insulation between the IC and underlying conductive paths, for example, the conductive trace and narrowed trace portion. Electrically insulating the IC from the conductive trace enables the IC to determine electromagnetic properties of the conductive trace without electrical contact. For example, the IC may determine the current through the conductive trace by measuring changes in the magnetic field around the conductive trace.

While this detailed description has set forth some embodiments of the present invention, the appended claims cover other embodiments of the present invention which differ from the described embodiments according to various modifications and improvements. For example, one skilled in the art may recognize that such principles may be applied to any integrated circuit in a lead-frame package benefitting from electrical insulation from a portion of the lead-frame package.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A lead-frame package comprising:
an integrated circuit substrate comprising at least a first surface and a second surface opposite the first surface, the integrated circuit substrate further comprising:
a plurality of conductive leads providing a conductive path between the second surface and the first surface,
a conductive trace formed within the integrated circuit substrate, and
an integrated insulating layer forming the first surface of the integrated circuit substrate, the integrated insulating layer defining a plurality of conductive wirebond pads associated with the plurality of conductive leads and providing an electrical connection to the plurality of conductive leads; and
an integrated circuit electrically isolated from the conductive trace by the integrated insulating layer, wherein the integrated circuit is positioned to determine an electromagnetic property of the conductive trace, and wherein the integrated circuit is electrically connected to the plurality of conductive leads.

2. The lead-frame package of claim 1, wherein the integrated circuit is configured to determine a current flow through the conductive trace based at least in part on the electromagnetic property.

3. The lead-frame package of claim 1, wherein a first portion of the conductive trace within a projection of an outer perimeter of the integrated circuit has a smaller cross-sectional area than a second portion of the conductive trace outside of the projection of the outer perimeter of the integrated circuit.

4. The lead-frame package of claim 3, wherein the first portion of the conductive trace is curved.

5. The lead-frame package of claim 1, wherein the integrated insulating layer comprises a dielectric buildup film.

6. The lead-frame package of claim 5, wherein the dielectric buildup film is between 40 and 60 micrometers thick.

7. The lead-frame package of claim 1, wherein the dielectric buildup film is integrated with the integrated circuit substrate.

8. The lead-frame package of claim 1, wherein the conductive wirebond pads providing an electrical connection to the plurality of conductive leads are each smaller than 10000 square micrometers.

9. The lead-frame package of claim 1, wherein the conductive leads are formed through a copper connection in molding (C2iM) process.

10. The lead-frame package of claim 1, wherein the integrated circuit is in a flip-chip configuration such that electrical contact points on the integrated circuit are between the first surface of the integrated circuit substrate and the integrated circuit.

11. The lead-frame package of claim 10, wherein an electrical connection is made between the electrical contact points on the integrated circuit and the plurality of conductive wirebond pads on the integrated circuit substrate.

12. The lead-frame package of claim 11, further comprising one or more adhesive connectors adhering the integrated circuit to the first surface of the integrated circuit substrate.

13. The lead-frame package of claim 1, wherein the integrated circuit is embedded in the lead-frame package between package molding and the integrated circuit substrate.

14. The lead-frame package of claim 13, wherein panel level package technology is utilized to embed the integrated circuit between the package molding and the integrated circuit substrate.

15. A method of manufacturing a lead-frame package, comprising:
forming an integrated circuit substrate comprising at least a first surface and a second surface opposite the first surface, the integrated circuit substrate defining a plurality of conductive leads providing a conductive path between the second surface and the first surface;
forming a conductive trace within the integrated circuit substrate;
disposing an integrated insulating layer on the integrated circuit substrate forming the first surface of the integrated circuit substrate, the integrated insulating layer defining a plurality of conductive wirebond pads associated with the plurality of conductive leads and providing an electrical connection to the plurality of conductive leads; and
positioning an integrated circuit on the first surface of the integrated circuit substrate, wherein the integrated circuit is electrically isolated from the conductive trace by the integrated insulating layer, wherein the integrated circuit is positioned to determine an electromagnetic property of the conductive trace, and wherein the integrated circuit is electrically connected to the plurality of conductive leads.

16. The method of claim 15, wherein the integrated insulating layer comprises a dielectric buildup film.

17. The method of claim 15, wherein the integrated circuit is configured to determine a current flow through the conductive trace based at least in part on the electromagnetic property.

18. The method of claim 15, wherein the integrated circuit substrate comprising the plurality of conductive leads and the conductive trace is formed through a copper connection in molding (C2iM) process.

19. The method of claim 15, wherein the integrated circuit is positioned such that a first portion of the conductive trace within a projection of an outer perimeter of the integrated circuit has a smaller cross-sectional area than a second portion of the conductive trace outside of the projection of the outer perimeter of the integrated circuit.

20. An electrical system, comprising:
a lead-frame package comprising:
an integrated circuit substrate comprising at least a first surface and a second surface opposite the first surface, the integrated circuit substrate further comprising:
a plurality of conductive leads providing a conductive path between the second surface and the first surface,
a conductive trace formed within the integrated circuit substrate, and
an integrated insulating layer forming the first surface of the integrated circuit substrate, the integrated insulating layer defining a plurality of conductive wirebond pads associated with the plurality of conductive leads and providing an electrical connection to the plurality of conductive leads; and
an integrated circuit electrically isolated from the conductive trace by the integrated insulating layer, wherein the integrated circuit is positioned to determine an electromagnetic property of the conductive trace, and wherein the integrated circuit is electrically connected to the plurality of conductive leads; and
a printed circuit board (PCB) comprising a current carrying conductive path and a plurality of conductive contact surfaces,
wherein the current carrying conductive path is configured to interface with the conductive trace by two or more of the plurality of conductive surfaces.
